(19) United States
(12) Patent Application Publication
(10) Pub. No.: US 2018/0011127 A1
(43) Pub. Date: Jan. 11, 2018

(54) KELVIN PROBE AND KELVIN INSPECTION UNIT PROVIDED WITH SAME

(71) Applicant: OMRON Corporation, Kyoto-shi, KYOTO (JP)

(72) Inventors: Hirotada TERANISHI, Osaka-shi (JP); Takahiro SAKAI, Moriyama-shi (JP)

(73) Assignee: OMRON Corporation, Kyoto-shi, KYOTO (JP)

(21) Appl. No.: 15/541,035

(22) PCT Filed: Jan. 5, 2016
(86) PCT No.: PCT/JP2016/050137

§ 371 Date: Jun. 30, 2017

(30) Foreign Application Priority Data
Jan. 6, 2015 (JP) 2015-001025

(51) Int. Cl. G01R 1/067; G01R 31/28; G01R 1/04

(52) U.S. Cl. CPC G01R 1/06722; G01R 1/04; G01R 31/2886

(57) ABSTRACT

A Kelvin probe according to one or more embodiments includes first and second probe pins in parallel to each other with a space in between. Each of the first and second probe pins includes: an elastic portion configured to expand and contract along a first line; a first contact on a second line parallel to the first line; and a second contact on the first line. The first and second contacts are directly electrically connected to each other, and supported such that at least one of the first and second contacts is reciprocally movable through an elastic force of the elastic portion. Both of the first contacts of the first and second probe pins are positioned between the first line of the first probe pin and the first line of the second probe pin when viewed on a plane comprising the first and second lines.

### TECHNICAL FIELD

The invention relates to a Kelvin probe and a Kelvin inspection unit provided with the same.

### BACKGROUND ART

Conventionally, a measurement method using a Kelvin connection (four-terminal measurement method) has been known as a method used for an electric connection test of a two-terminal circuit. In the measurement method using a Kelvin connection, a probe pin is connected to each terminal of a two-terminal circuit, and the current and voltage are separately measured.

A Kelvin inspection unit used for the measurement method using a Kelvin connection is described, for example, in Patent Document 1. This Kelvin inspection unit includes Kelvin probes, each having two probe pins arranged in parallel to each other.

### CITATION LIST

### Patent Document

PATENT DOCUMENT 1: Japanese Patent Application Publication No. 2006-140037

### SUMMARY OF INVENTION

### Technical Problem

The Kelvin probe described above has four contacts, respectively formed at both ends of the probe pins. However, there has been a problem that downsizing is difficult because of the complexity of the shape of these four contacts.

In view of the above problem, an object of the invention is to provide a Kelvin probe suitable for downsizing and a Kelvin inspection unit provided with the same.

### Solution to Problem

To solve the above problem, a Kelvin probe includes first and second probe pins arranged in parallel to each other with a space in between, and each of the first and second probe pins includes: an elastic portion configured to expand and contract along a first line; a first contact arranged on a second line parallel to the first line; and a second contact arranged on the first line. The first and second contacts are directly electrically connected to each other, and supported such that at least one of the first and second contacts is reciprocally movable through an elastic force of the elastic portion. Both of the first contacts of the first and second probe pins are arranged between the first line of the first probe pin and the first line of the second probe pin when viewed on a plane including the first and second lines.

### Advantageous Effects of Invention

According to the probe pins of the invention, both of the first contacts of the first and second probe pins are arranged between the second line of the first probe pin and the second line of the second probe pin when viewed on the plane including the first and second lines. This makes it possible to obtain a Kelvin probe with a simple configuration, adapted to narrowing a pitch between terminals and suitable for downsizing.

As an embodiment of the invention, the configuration may be such that the elastic portion is a coil spring, and each of the first and second probe pins includes: a first plunger including a first insertion portion configured to be inserted into one end of the coil spring, and a first contact portion provided with the first contact; and a second plunger including a second insertion portion configured to be inserted into the other end of the coil spring, and a second contact portion provided with the second contact.

According to this embodiment, even when the first and second probe pins are downsized, it is easy to obtain a spring load necessary for the design.

According to an embodiment of the invention, the configuration may be such that the first and second plungers are formed by electroforming.

This embodiment makes it easy to obtain a Kelvin probe suitable for downsizing.

According to an embodiment of the invention, the configuration may be such that the elastic portion is a serpentine portion including straight portions and curve portions connecting adjacent ones of the straight portions, each of the first and second probe pins includes a first contact portion provided with the first contact and a second contact portion provided with the second contact, and the first and second contact portions and the elastic portion are integrally formed.

According to this embodiment, since the first and second probe pins are integrally formed, it is possible to eliminate the assembly process and improve the productivity.

According to an embodiment of the invention, the configuration is such that the first and second probe pins are formed by electroforming.

This embodiment makes it easy to obtain a Kelvin probe suitable for downsizing.

According to an embodiment of the invention, the configuration may be such that the Kelvin probe further includes a holder integrally holding the first and second probe pins.

According to this embodiment, the first and second probe pins are integrally held with the holder. This makes it possible to position the first and second probe pins precisely, making the assembly easy, and thereby improving the productivity.

A Kelvin inspection unit according to the invention includes the Kelvin probe described above and a housing to house the Kelvin probe.

The Kelvin inspection unit of the invention makes it possible to obtain a Kelvin inspection unit provided with the Kelvin probe suitable for downsizing.

### BRIEF DESCRIPTION OF DRAWINGS

FIG. 1 is a perspective view of an example of a Kelvin inspection unit provided with a Kelvin probe of a first embodiment of the invention.

FIG. 2 is a cross-sectional view taken along line II-II in FIG. 1.

FIG. 3 is a perspective view of the Kelvin probe of the first embodiment of the invention.

FIG. 4 is a view taken in the direction of arrow IV of the Kelvin probe illustrated in FIG. 3.

FIG. 5 is a view taken in the direction of arrow V of the Kelvin probe illustrated in FIG. 3.

FIG. 6 is an exploded perspective view of the Kelvin probe illustrated in FIG. 3.

FIG. 7 is a perspective view of an example of a Kelvin inspection unit provided with a Kelvin probe of a second embodiment of the invention.

FIG. 8 is a cross-sectional view taken along line VIII-VIII in FIG. 7.

FIG. 9 is a perspective view of the Kelvin probe of the second embodiment of the invention.

FIG. 10 is a view taken in the direction of arrow X of the Kelvin probe illustrated in FIG. 9.

FIG. 11 is a view taken in the direction of arrow XI of the Kelvin probe illustrated in FIG. 9.

FIG. 12 is an exploded perspective view of the Kelvin probe illustrated in FIG. 9.

FIG. 13 is a perspective view of an example of a Kelvin inspection unit provided with a Kelvin probe of a third embodiment of the invention.

FIG. 14 is a cross-sectional view taken along line XIVI-XIV in FIG. 13.

FIG. 15 is a perspective view of the Kelvin probe of the third embodiment of the invention.

FIG. 16 is a view taken in the direction of arrow XVI of the Kelvin probe illustrated in FIG. 15.

FIG. 17 is a view taken in the direction of arrow XVII of the Kelvin probe illustrated in FIG. 15.

### DESCRIPTION OF EMBODIMENTS

Hereinafter, descriptions are provided for embodiments of Kelvin inspection units provided with a Kelvin probe of the invention with reference to the attached drawings. Note that the although following descriptions use the terms indicating directions such as “upper”, “lower”, “left”, and “right” and other terms including such terms to explain configurations illustrated in the drawings, the purpose of the use of those terms is to facilitate understanding of the embodiments through the drawings. Therefore, those terms do not necessarily indicate directions in the state where the embodiments of the invention are actually used, and it is not to be interpreted that the technical scope of the invention described in claims is limited by those terms.

### First Embodiment

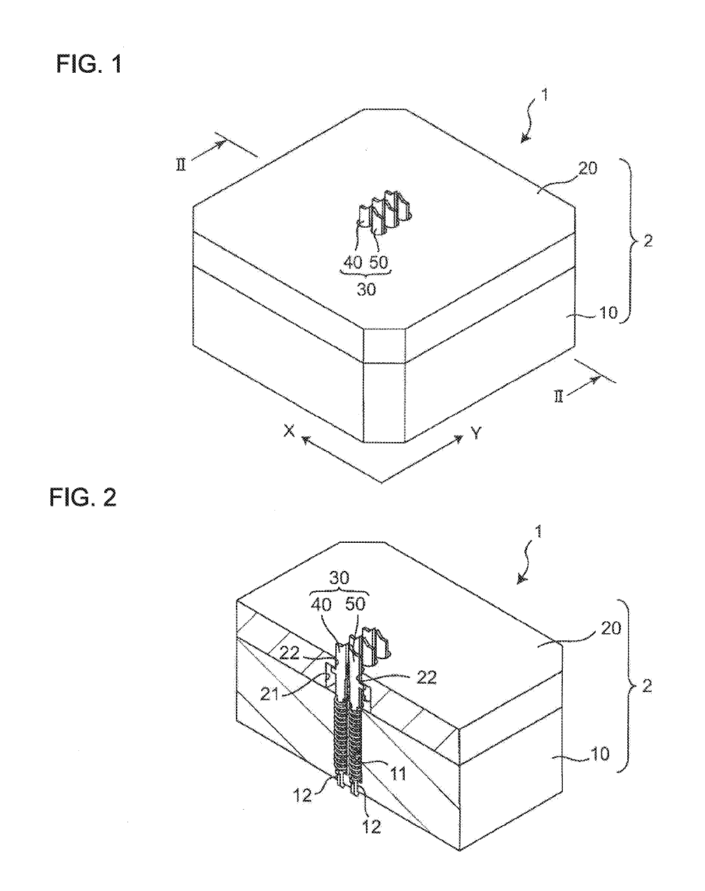

FIG. 1 is a perspective view of an example of a Kelvin inspection unit provided with a Kelvin probe according to a first embodiment of the invention, and FIG. 2 is a cross-sectional view taken along line II-II in FIG. 1.

As illustrated in FIGS. 1 and 2, Kelvin inspection unit 1 includes housing 2 and Kelvin probe 30 of the first embodiment housed in housing 2. Housing 2 includes housing main body 10 and housing cover 20 that covers housing main body 10, and Kelvin probe 30 is housed in housing main body 10.

As illustrated in FIG. 1, housing main body 10 in a top view has a flat shape of a square with the four corners chamfered. Substantially at the center of this housing main body 10, storage sections 11 are provided to house Kelvin probes 30.

Storage sections 11, each having a circular shape in a top view, are arranged in parallel to and apart from each other along X direction and Y direction illustrated in FIG. 1. At the bottom surface of each storage section 11, contact opening 12 is provided through which one end of Kelvin probe 30 protrudes. Contact opening 12 has a circular shape with a diameter smaller than that of storage section 11 in a top view. Note that X direction is a direction parallel to a side of housing main body 10 in a top view, and direction Y is a direction normal to X direction.

As illustrated in FIG. 1, housing cover 20 in a top view has the same flat shape as that of housing main body 10. As illustrated in FIG. 2, this housing cover 20 has recess 21 provided substantially at the center of the bottom surface thereof.

Recess 21 has a rectangular shape in a cross-sectional view and contact openings 22 are provided at the bottom thereof, through which the other ends of Kelvin probes 30 protrude. This contact openings 22, each having a circular shape in a top view, correspond to storage sections 11 of housing main body 10 one-to-one, and are arranged apart from each other along X and Y directions illustrated in FIG. 1 in the same manner as in storage sections 11. In addition, contact openings 22 are arranged in a top view such that the center position of each contact opening 22 coincides with the center position of corresponding storage section 11 of housing main body 10.

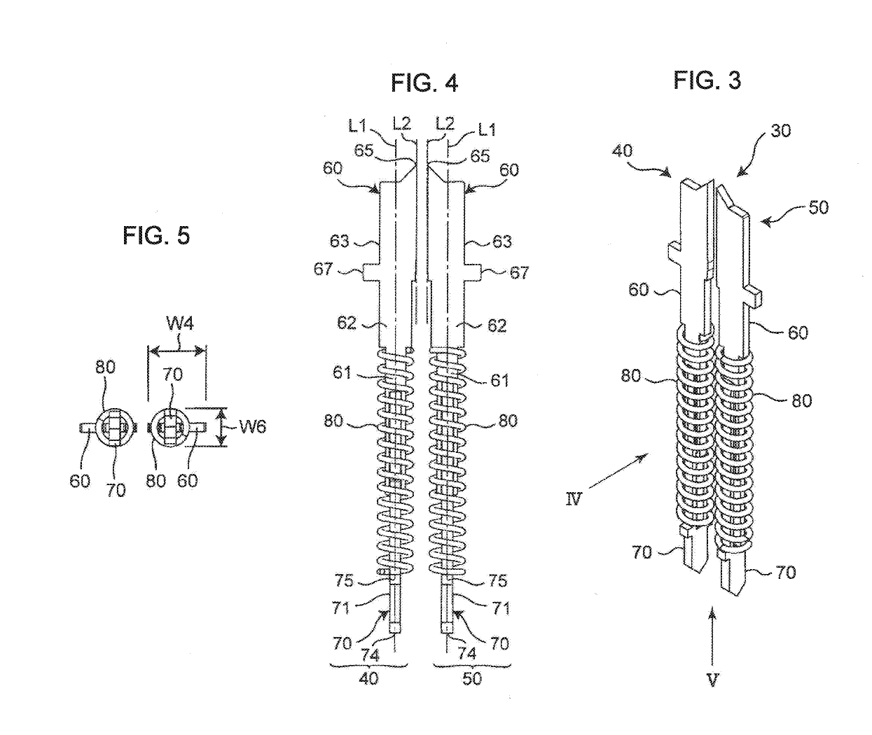

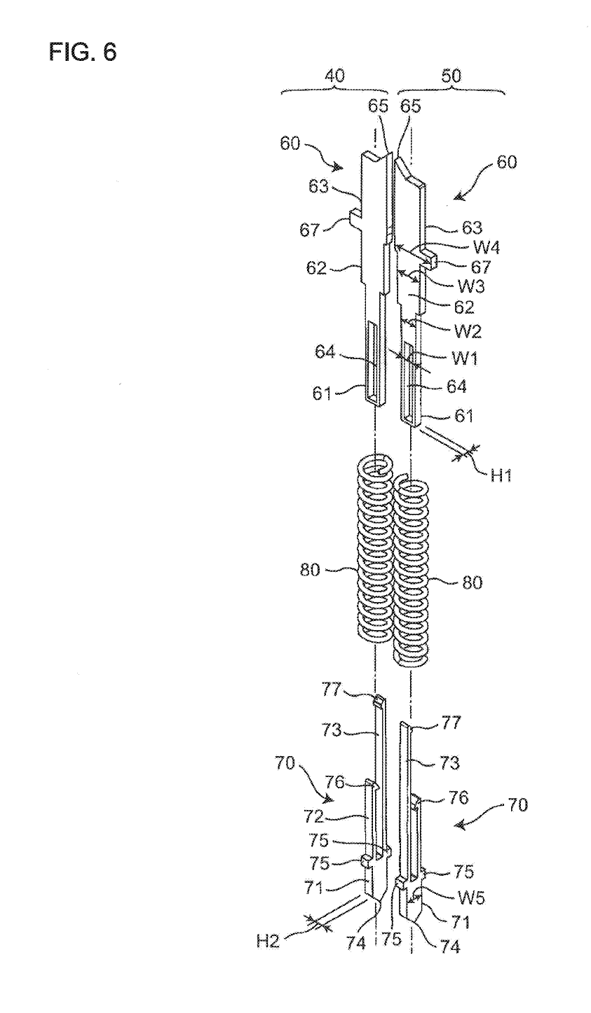

FIG. 3 is a perspective view of Kelvin probe 30 of the first embodiment. FIG. 4 is a view taken in the direction of arrow IV of the Kelvin probe illustrated in FIG. 3, and FIG. 5 is a view taken in the direction of arrow V of the Kelvin probe illustrated in FIG. 3. In addition, FIG. 6 is an exploded perspective view of the Kelvin probe in FIG. 4.

Kelvin probe 30 of the first embodiment includes first probe pin 40 and second probe pin 50 as illustrated in FIGS. 3 to 6. First and second probe pins 40 and 50 each have the same configuration. For this reason, the explanation for first probe pin 40 is referred to also for second probe pin 50.

As illustrated in FIG. 6, first probe pin 40 includes first plunger 60, second plunger 70, and coil spring 80. Both first and second plungers 60 and 70 are conductive and formed, for example, by electroforming.

As illustrated in FIG. 6, first plunger 60 has a flat plate shape extending linearly and is formed with substantially the same thickness H1. This first plunger 60 includes clamped portion 61 as an example of a first insertion portion, middle portion 62 continuing to clamped portion 61, and contact portion 63 as an example of a first contact portion continuing to middle portion 62. Note that the surfaces normal to the direction of thickness H1 of first plunger 60 are regarded as main surfaces, and the surfaces normal to the main surfaces and parallel to the direction of thickness H1 are regarded as side surfaces.

Clamped portion 61 has guide slot 64 having a rectangular shape and passing through the main surfaces. Guide slot 64 extends in clamped portion 61 from the distal end (the lower end in FIG. 6) toward the proximal end (the upper end in FIG. 6) which continues to middle portion 62. Guide slot 64 has width W1 which is larger than thickness H2 of second plunger 70.

Middle portion 62 has width W3 which is larger than width W2 of clamped portion 61 and substantially equal to the outer diameter of coil spring 80.

Contact portion 63 has first contact 65 protruding from the distal end thereof (the upper end in FIG. 6). First contact 65, having a right-angled triangle when viewed in the main surface, is provided to be located on one side surface of contact portion 63. Contact portion 63 also has housing support portion 67 at the proximal end thereof (the lower end in FIG. 6). Housing support portion 67 is provided to protrude from the other side surface opposed to the side surface on which first contact 65 is located. The portion of contact portion 63 at which housing support portion 67 is provided has width W4 (indicated in FIG. 5) larger than the diameter of contact opening 22 of housing cover 20.

As illustrated in FIG. 6, second plunger 70 has a flat plate shape extending linearly and is formed with substantially the same thickness H2. This second plunger 70 includes contact portion 71 as an example of a second contact portion and first and second elastic pieces 72 and 73, as an example of a second insertion portion, provided at the proximal end (the upper end in FIG. 6) of contact portion 71. Note that the surfaces normal to the direction of thickness H2 of second plunger 70 are regarded as main surfaces, and the surfaces normal to the main surfaces and parallel to the direction of thickness H2 are regarded as side surfaces.

Contact portion 71 has a substantially rectangular flat plate shape, and is provided with second contact 74 having a V shape, when viewed in the main surface, at the distal end (the lower end in FIG. 6). Contact portion 71 is also provided with coil spring supports 75 protruding on the side surfaces at the proximal end (the upper end in FIG. 6).

First and second elastic pieces 72 and 73 extend substantially in parallel to each other with a space in between from the proximal end of contact portion 71 along the longitudinal direction of contact portion 71. First and second elastic pieces 72 and 73 are arranged at both ends in width W5 direction of the proximal end of contact portion 71 to have a distance therebetween larger than thickness H1 of first plunger 60. In other words, first and second elastic pieces 72 and 73 are provided such that the distance between the outer surfaces is substantially equal to width W5 of contact portion 71 and the distance between the inner surfaces is larger than thickness H1 of first plunger 60. In addition, first and second elastic pieces 72 and 73 have different lengths, and first elastic piece 72 is shorter than second elastic piece 73.

At the distal end of the inner surface of first elastic piece 72, guide protrusion 76 is provided to protrude toward second elastic piece 73. In addition, at the distal end of the inner surface of second elastic piece 73, contact protrusion 77 is provided to protrude toward first elastic piece 72. Contact protrusion 77 is arranged to be always in contact with clamped portion 61 of first plunger 60 in the state where guide protrusion 76 of first elastic piece 72 is fitted in guide slot 64 of first plunger 60.

Coil spring 80 is an example of an elastic portion and made, for example, of carbon steel or stainless steel. As illustrated in FIGS. 3 to 5, coil spring 80 has an inner diameter a little larger than width W2 (indicated in FIG. 6) of clamped portion 61 of first plunger 60 and width W5 (indicated in FIG. 6) of second plunger 70. In addition, coil spring 80 has an outer diameter substantially equal to width W3 (indicated in FIG. 6) of middle portion 62 of first plunger 60 and width W6 (indicated in FIG. 5) at the portion at which coil spring supports 75 of second plunger 70 are provided.

Note that the length of coil spring 80 is adjusted to be always in compression in the state illustrated in FIGS. 1 and 2, in other words, in the state where first plunger 60 and second plunger 70 are assembled to each other and housed in housing 2 of Kelvin inspection unit 1.

Next, descriptions are provided for an assembly process of Kelvin inspection unit 1 provided with Kelvin probe 30.

First, each of first and second probe pins 40 and 50 is assembled. To begin with, first plunger 60 is inserted, with the clamped portion 61 side inward, through one end of coil spring 80 into the inside of coil spring 80, while second plunger 70 is inserted, with first and second elastic pieces 72 and 73 side inward, through the other end of coil spring 80 into the inside of coil spring 80. At this time, as illustrated in FIG. 5, first and second plungers 60 and 70 are inserted such that the main surfaces of first plunger 60 and the main surfaces of second plunger 70 are orthogonal to each other.

When first and second plungers 60 and 70 are continuously inserted into coil spring 80, clamped portion 61 of first plunger 60 is inserted between first and second elastic pieces 72 and 73 of second plunger 70, and clamped portion 61 is clamped by first elastic piece 72 and second elastic piece 73. Then, when first and second plungers 60 and 70 are further inserted into coil spring 80, guide protrusion 76 of second plunger 70 is fitted in guide slot 64 of first plunger 60, and first and second plungers 60 and 70 are connected to each other. As a result, assembly of first and second probe pins 40 and 50 is completed.

In first and second probe pins 40 and 50 that are assembled, contact protrusion 77 of second elastic piece 73 of second plunger 70 is always in contact with the proximal side (the upper side of guide slot 64 in FIG. 6) of clamped portion 61 of first plunger 60. In other words, in first and second probe pins 40 and 50 in this condition, first and second contacts 65 and 74 are directly electrically connected to each other.

After assembly of first and second probe pins 40 and 50 is completed, assembled first and second probe pins 40 and 50 are inserted, with second plunger 70 side inward, into storage sections 11 of housing main body 10 to form Kelvin probe 30. At this time, as illustrated in FIG. 4, first and second probe pins 40 and 50 are inserted into storage sections 11 such that the sides on which the first contacts 65 of first plungers 60 are located face to each other.

In other words, in Kelvin probe 30 in the view taken in the direction of arrow IV illustrated in FIG. 4, second contacts 74 of first and second probe pins 40 and 50 are arranged on first lines L1 which are the center lines of coil springs 80 of first and second probe pins 40 and 50, and first contacts 65 of first and second probe pins 40 and 50 are arranged on second lines L2 parallel to first lines L1. Second lines L2 of first and second probe pins 40 and 50 are arranged between first lines L1 of first and second probe pins 40 and 50.

Then, a process of assembling first and second probe pins 40 and 50, and a process of inserting assembled first and second probe pins 40 and 50 into storage sections 11 of housing main body 10 to form Kelvin probe 30 are repeated. After first and second probe pins 40 and 50 are inserted into all storage sections 11 of housing main body 10, housing cover 20 is attached to housing main body 10, and the assembly process of Kelvin inspection unit 1 is completed.

Next, descriptions are provided for operation of Kelvin probe 30 housed in Kelvin inspection unit 1.

As illustrated in FIG. 2, in Kelvin probe 30 housed in Kelvin inspection unit 1, parts of contact portions 63 including first contacts 65 of first plungers 60 are protruded from contact openings 22 of housing cover 20. In addition, parts of contact portions 71 including second contacts 74 of second plungers 70 are protruded from contact openings 12 of housing main body 10. First and second probe pins 40 and 50 are arranged to be parallel with each other with a space in between by storage sections 11 of housing main body 10 and contact openings 22 of housing cover 20 corresponding to these storage sections 11. First and second probe pins 40 and 50 are housed in Kelvin inspection unit 1 in this initial condition so as to each operate independently without coming into contact with each other.

In this initial condition, first plunger 60 receives restoration force of coil spring 80 at middle portion 62 and is pressed against housing cover 20 through housing support portion 67, and second plunger 70 receives restoration force of coil spring 80 at coil spring supports 75 and is pressed against housing main body 10 through coil spring supports 75.

When first and second plungers 60 and 70 are pushed into housing 2 of Kelvin inspection unit 1 with forces being applied to first and second contacts 65 and 74 of first and second plungers 60 and 70 of each of first and second probe pins 40 and 50, guide protrusion 76 of first elastic piece 72 of second plunger 70 starts sliding along guide slot 64 of first plunger 60. At this time, coils spring 80 is gradually compressed by the forces applied to first and second plungers 60 and 70 and conveyed to coil spring 80 through middle portion 62 of first plunger 60 and coil spring supports 75 of second plunger 70.

When first and second plungers 60 and 70 are further pushed into housing 2 of Kelvin inspection unit 1, guide slot 64 of first plunger 60 and guide protrusion 76 of second plunger 70 come into contact with each other, and the slide movement of first and second plungers 60 and 70 stops. Otherwise, before guide slot 64 of first plunger 60 and guide protrusion 76 of second plunger 70 come into contact with each other, first and second contacts 65 and 74 of first and second plungers 60 and 70 are completely pushed into housing 2, and the slide movement of first and second plungers 60 and 70 stops.

After the slide movement of first and second plungers 60 and 70 stop, when the forces applied to first and second contacts 65 and 74 of first and second plungers 60 and 70 are released, the restoration force of coil spring 80 urges first plunger 60 toward housing cover 20, and second plunger 70 toward housing main body 10. As a result, first and second plungers 60 and 70 return to the initial condition illustrated in FIG. 2. In this manner, first contact 65 of first plunger 60 and second contact 74 of second plunger 70 are supported to be reciprocally movable through the elastic force of coil spring 80.

Note that first and second probe pins 40 and 50 are arranged to be parallel with each other with a space in between by storage sections 11 of housing main body 10 and contact openings 22 of housing cover 20 corresponding to storage sections 11, and each operate independently without coming into contact with each other.

As illustrated in FIG. 4, in Kelvin probe 30 of the first embodiment, both of the first contacts 65 of first and second probe pins 40 and 50 are arranged between second line L2 of first probe pin 40 and second line L2 of second probe pin 50 in the view taken in the direction of arrow IV, in other words, when viewed on the plane including first lines L1 and second lines L2. This makes it possible to obtain a Kelvin probe with a simple configuration, adapted to narrowing a pitch between terminals and suitable for downsizing.

In addition, in Kelvin probe 30 of the first embodiment, coil spring 80 causes first and second contacts 65 and 74 of first and second plungers 60 and 70 to return to the initial condition illustrated in FIG. 2. For this reason, even when first and second probe pins 40 and 50 are downsized, it is easy to obtain a spring load necessary for the design.

In addition, in Kelvin probe 30 of the first embodiment, contact protrusion 77 of second elastic piece 73 of second plunger 70 is always in contact with the proximal side of clamped portion 61 of first plunger 60 (the upper side of guide slot 64 in FIG. 6). This makes it possible to obtain high contact stability between first and second plungers 60 and 70.

In addition, in Kelvin probe 30 of the first embodiment, guide protrusion 76 of second plunger 70 slides along guide slot 64 of first plunger 60. This makes it possible to precisely detect the contact position where clamped portion 61 of first plunger 60 and contact protrusion 77 of second plunger 70 are in contact with each other.

### Second Embodiment

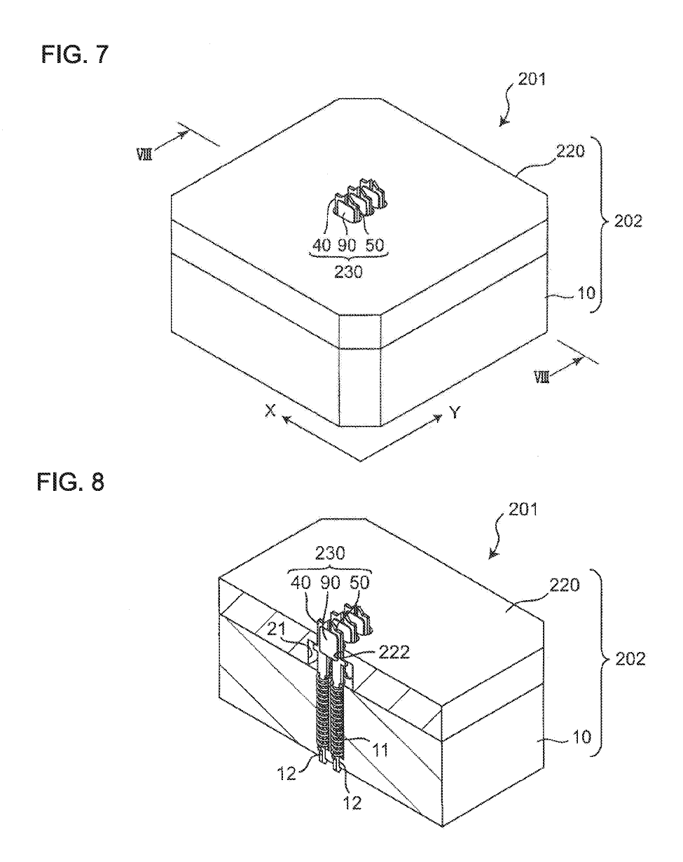

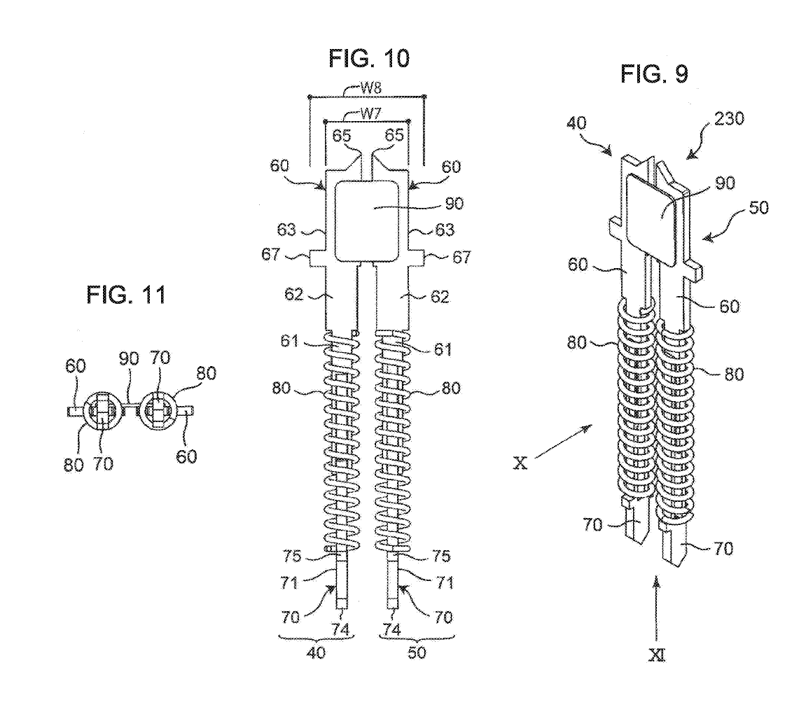

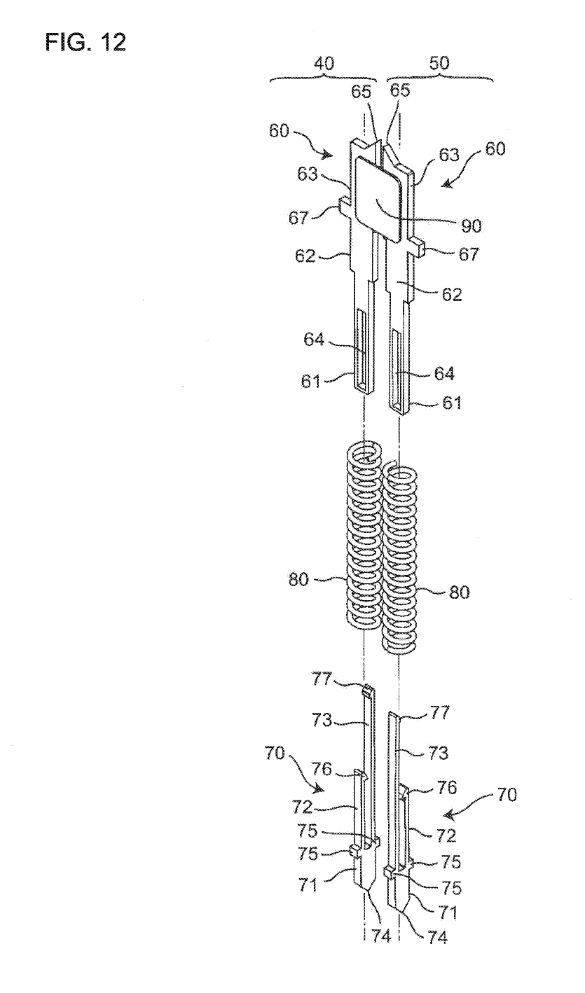

FIGS. 7 to 12 are diagrams illustrating Kelvin probe 230 of a second embodiment and an example of Kelvin inspection unit 201 provided with Kelvin probe 230 of the second embodiment. In this second embodiment, the same portions as in the first embodiment are denoted by the same reference signs, descriptions thereof are omitted, and descriptions are provided for points different from the first embodiment.

As illustrated in FIGS. 7 and 8, Kelvin inspection unit 201 provided with Kelvin probe 230 of the second embodiment is different from inspection unit 1 provided with Kelvin probe 30 of the first embodiment in that housing cover 220 of housing 202 is provided with contact openings 222, each having an oval shape in a top view.

As illustrated in FIGS. 7 and 8, contact openings 222 of housing cover 220, each having an oval shape in a top view the major axis of which extends in X direction indicated in FIG. 7, are arranged apart from each other along Y direction indicated in FIG. 7. As illustrated in FIG. 2, this contact opening 222 has a diameter in the major axis direction which is larger than width W7 (indicated in FIG. 10) of contact portion 63 of first and second probe pins 40 and 50 and smaller than width W8 (indicated in FIG. 10) which is the sum of width W7 of contact portion 63 of first and second probe pins 40 and 50 and the protrusion lengths of housing support portions 67.

Kelvin probe 230 of the second embodiment is different from Kelvin probe 30 of the first embodiment in that Kelvin probe 230 includes holder 90 which integrally holds first and second probe pins 40 and 50.

Holder 90 of Kelvin probe 230 is made of an insulating material, provided on the main surfaces on one side of first and second probe pins 40 and 50, and arranged to cover parts of contact portions 63 of first plungers 60 of first and second probe pins 40 and 50. This holder 90 allows first and second probe pins 40 and 50 to be integrally held in parallel with each other with a space in between.

Note that holder 90 is formed, for example, from the same material as the insulation material used when first and second plungers 60 and 70 of first and second probe pins 40 and 50 are formed by electroforming.

As described above, in Kelvin probe 230 of the second embodiment, holder 90 integrally holds first and second probe pins 40 and 50. This makes it easy to house first and second probe pins 40 and 50 in housing 2 and makes the assembly easy even if they are downsized, compared to the case where first and second probe pins 40 and 50 are housed individually in housing 2.

In addition, in Kelvin inspection unit 201 provided with Kelvin probe 230 of the second embodiment, contact openings 222 are provided through which one end of integrated first and second probe pins 40 and 50 protrudes. This reduces the number of the contact openings to be formed and allows the size of the contact opening to be larger, compared to the Kelvin inspection unit provided with contact openings respectively corresponding to all of first and second probe pins 40 and 50. This makes the assembly of Kelvin inspection unit 201 easy, improving the productivity, even if Kelvin probe 230 is downsized.

### Third Embodiment

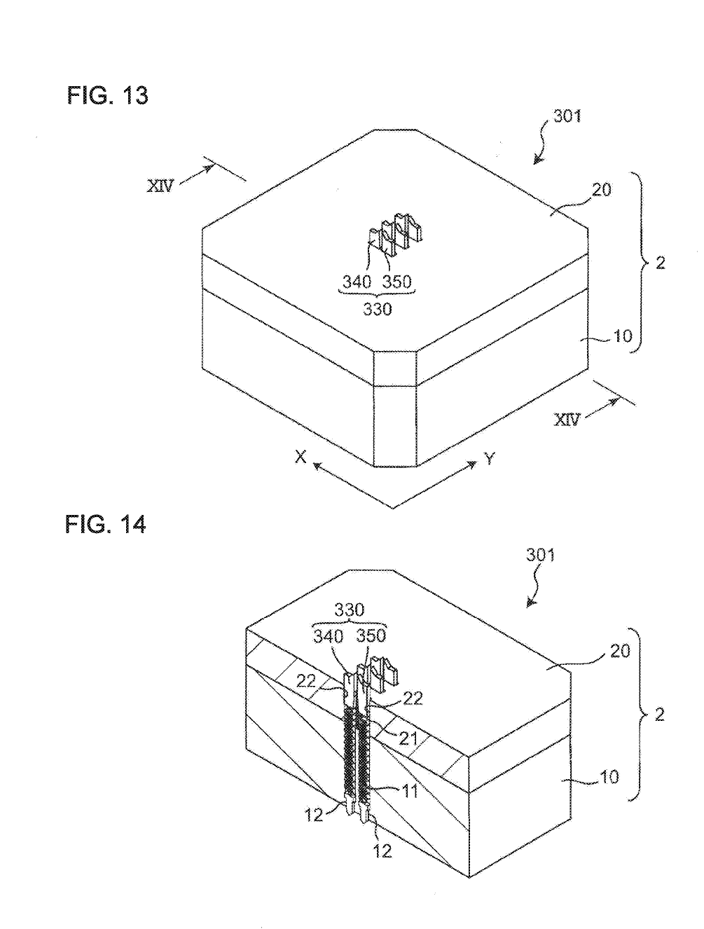

FIGS. 13 to 17 are diagrams illustrating Kelvin probe 330 of a third embodiment and an example of Kelvin inspection unit 301 provided with Kelvin probe 330 of the third embodiment. In this third embodiment, the same portions as in the first embodiment are denoted by the same reference signs, descriptions thereof are omitted, and descriptions are provided for points different from the first embodiment.

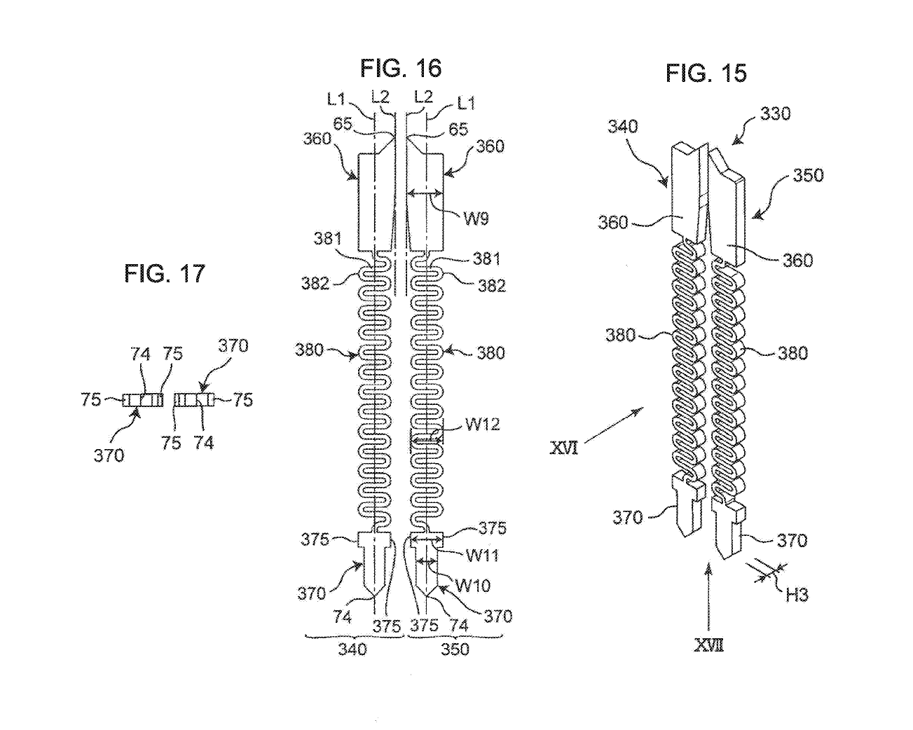

As illustrated in FIGS. 15 to 17, Kelvin probe 330 of the third embodiment includes first probe pin 340 and second probe pin 350. First and second probe pins 340 and 350 each have the same configuration. For this reason, the explanation for first probe pin 340 is referred to also for second probe pin 350.

As illustrated in FIGS. 15 and 16, first probe pin 340 has a flat plate shape extending linearly and is formed with substantially the same thickness H3. This first probe pin 340 includes first contact portion 360, second contact portion 370, and serpentine portion 380, which is an example of an elastic portion, connected to first and second contact portions 360 and 370, and is integrally formed, for example, by electroforming. Note that the surfaces viewed in the direction of arrow XVI illustrated in FIG. 16 are regarded as main surfaces, and the surfaces normal to the main surfaces are regarded as side surfaces.

First contact portion 360 has first contact 65 protruding from the distal end thereof (the upper end in FIG. 16) and is formed with substantially the same width W9. One end of serpentine portion 380 is connected to the proximal end (the lower end in FIG. 16) of first contact portion 360 on first line L1.

Second contact portion 370 has second contact 74 having a V shape, when viewed in the main surface, at the distal end thereof (the lower end in FIG. 16), and is formed with the same width W10. In addition, support protrusions 375 are provided to protrude on the side surfaces of the proximal end (the upper end in FIG. 16) of second contact portion 370, and the other end of serpentine portion 380 is connected to the proximal end of second contact portion 370 on first line L1. Note that second contact portion 370 is formed with width W10 which is smaller than width W9 of first contact portion 360. In addition, support protrusions 375 are formed such that width W11, which is the sum of the protrusion lengths thereof and width W10 of second contact portion 370, is substantially equal to width W9 of first contact portion 360.

Serpentine portion 380 is formed with the same width W12 and has straight portions 381 and circular arc portions 382 connecting adjacent straight portions 381. Straight portions 381 are arranged to extend in parallel in the direction of width W12 in the free state illustrated in FIG. 16. Note that serpentine portion 380 is formed such that width W12 thereof is substantially equal to width W9 of first contact portion 360 and width W11 at the support protrusions of second contact portion 370.

Next, descriptions are provided for an assembly process of Kelvin inspection unit 301 provided with Kelvin probe 330.

To begin with, first and second probe pins 340 and 350 are inserted into storage sections 11 of housing main body 10, with second contact portion 370 sides inward, to form Kelvin probe 330.

By repeating the process of inserting first and second probe pins 340 and 350 into storage sections 11 of housing main body 10 to form Kelvin probe 30, first and second probe pins 340 and 350 are inserted into all of storage sections 11 of housing main body 10. Then, housing cover 20 is attached to housing main body 10, and the assembly process of Kelvin inspection unit 301 is completed.

For Kelvin probes 330 housed in inspection unit 301 in this condition as illustrated in FIG. 14, parts of first contact portions 360 including first contacts 65 are protruded from contact openings 22 of housing cover 20. In addition, parts of second contact portions 370 including second contacts 74 are protruded from contact openings 12 of housing main body 10. First and second probe pins 340 and 350 are housed in Kelvin inspection unit 1 in this initial condition.

In this initial condition, first and second probe pins 340 and 350 are held being engaged at the bottom surface of storage sections 11 of housing main body 10 through support protrusions 375 of second contact portions 370.

Next, descriptions are provided for operation of Kelvin probe 330 housed in Kelvin inspection unit 301.

When a force is applied to first contact 65 of first contact portion 360 of each of first and second probe pins 340 and 350 in the initial condition, serpentine portion 380 is compressed and first contact portion 360 is pushed into housing 2 of Kelvin inspection unit 301.

When first contact portion 360 is further pushed into housing 2 of Kelvin inspection unit 301 by applying the forces to first contact 65, adjacent straight portions 381 of serpentine portion 380 come into contact with each other, and the movement of first contact portions 360 stop. Otherwise, before adjacent straight portions 381 of serpentine portion 380 come into contact with each other, first contact 65 of first contact portion 360 is completely pushed into housing 2, and the movement of first contact portion 360 stops.

After first contact portion 360 stops moving, when the force applied to first contact 65 of first contact portion 360 is released, a restoration force of serpentine portion 380 urges first contact portion 360 toward housing cover 20. As a result, first contact portion 360 returns to the initial condition illustrated in FIG. 14. As described above, first contact 65 of first contact portion 360 is supported to be reciprocally movable through an elastic force of serpentine portion 380.

As above, in Kelvin probe 330 of the third embodiment, first and second probe pins 340 and 350 are integrally formed. This makes it possible to eliminate a process of assembling probe pins 340 and 350, improving the productivity. Even if Kelvin probe 330 is downsized, probe pins 340 and 350 are easy to house in housing 2. This makes the assembly of Kelvin inspection unit 301 easy, improving the productivity.

### Other Embodiments

In the first and second embodiments, as for first contact 65, second lines L2 passing through first contacts 65 only need to be between first line L1 of first probe pin 40 and first line L1 of second probe pin 50 when viewed on the plane including first lines L1 and second lines L2, and may be arranged in any position within this area.

In the first and second embodiments, guide protrusion 76 of first elastic piece 72 only needs to be capable of being fitted in guide slot 64, and limiting, when fitted in guide slot 64, the slide movement of first and second plungers 60 and 70 within guide slot 64, and the shape, size, or the like of the guide protrusion 76 may be selected as appropriate.

In the first and second embodiments, the shape, size, and the like of contact protrusion 77 of second elastic piece 73 may be selected as appropriated depending on design. By changing the shape or the like of contact protrusion 77, the bias force against each clamped portion of second elastic piece 73 can be adjusted.

In the first to third embodiments, although the thicknesses of first and second plungers 60 and 70 and first and second probe pins 340 and 350 are the same, the invention is not limited to this. The thicknesses of first and second plungers 60 and 70 and first and second probe pins 340 and 350 may be changed as appropriate. Alternatively, the thicknesses may vary for each part of first and second plungers 60 and 70, and first and second probe pins 340 and 350.

First and second plungers 60 and 70 and first and second probe pins 340 and 350 in the first to third embodiments may have treated surfaces such as plating and coating depending on the design.

Although first and second plungers 60 and 70 and first and second probe pins 340 and 350 in the first to third embodiments are formed by electroforming, the invention is not limited to this. Any method may be selected as long as first and second plungers 60 and 70 and first and second probe pins 340 and 350 in the first to third embodiments can be formed by the method.

In the first and second embodiments, first plunger 60 is provided with clamped portion 61 having guide slot 64, and second plunger 70 is provided with first and second elastic pieces 72 and 73. However, the invention is not limited to this. For example, in the first and second embodiments, the first plunger may be provided with the first and second elastic pieces, and the second plunger may be provided with the guide slot.

For first and second plungers 60 and 70 of the first and second embodiments, the configuration is not limited to the combination of clamped portion 61 having guide slot 64 and first and second elastic pieces 72 and 73, but any configuration may be employed, as long as first and second plungers 60 and 70 are capable of sliding relative to each other and being electrically connected when inserted from both ends of coil spring 80.

It is a matter of course that constituents described in the first to third embodiments and the modification examples may be combined as appropriate, and that they may be selected, replaced, or deleted as appropriate.

### INDUSTRIAL APPLICABILITY

A Kelvin probe and a Kelvin inspection unit according to the invention are applicable, for example, to an inspection unit for semiconductor integrated circuits and semiconductor devices.

### REFERENCE SIGNS LIST

1, 201, 301 Kelvin inspection unit
2 housing
10 housing main body
11 storage section
12 contact opening
20 housing cover
21 recess
22 contact opening
30, 230, 330 Kelvin probe
40, 340 first probe pin
50, 350 second probe pin
61 first plunger
61 clamped portion
62 middle portion
63 contact portion
64 guide slot
65 first contact
67 housing support portion
70 second plunger
71 contact portion
72 first elastic piece
73 second elastic piece
74 second contact
75 coil spring support
76 guide protrusion
77 contact protrusion
80 coil spring
360 first contact portion
370 second contact portion
375 support protrusion
380 serpentine portion
381 straight portion
382 circular arc portion

1. A Kelvin probe comprising first and second probe pins in parallel to each other with a space in between, each of the first and second probe pins comprising:
an elastic portion configured to expand and contract along a first line;
a first contact on a second line parallel to the first line; and
a second contact on the first line, wherein
the first and second contacts are directly electrically connected to each other, and supported such that at least one of the first and second contacts is reciprocally movable through an elastic force of the elastic portion, and
both of the first contacts of the first and second probe pins are positioned between the first line of the first probe pin and the first line of the second probe pin when viewed on a plane comprising the first and second lines.

2. The Kelvin probe according to claim 1, wherein
the elastic portion comprises a coil spring, and
each of the first and second probe pins comprises:
a first plunger comprising a first insertion portion inserted into one end of the coil spring, and a first contact portion provided with the first contact; and
a second plunger comprising a second insertion portion inserted into the other end of the coil spring, and a second contact portion provided with the second contact.

3. The Kelvin probe according to claim 2, wherein the first and second plungers are formed by electroforming.

4. The Kelvin probe according to claim 1, wherein
the elastic portion comprises a serpentine portion comprising straight portions and circular arc portions connecting adjacent ones of the straight portions,
each of the first and second probe pins comprises a first contact portion provided with the first contact and a second contact portion provided with the second contact, and
the first and second contact portions and the elastic portion are integrally formed.

5. The Kelvin probe according to claim 4, wherein the first and second probe pins are formed by electroforming.

6. The Kelvin probe according to claim 1, further comprising a holder integrally holding the first and second probe pins.

7. A Kelvin inspection unit comprising
the Kelvin probe according to claim 1 and
a housing to house the Kelvin probe.

8. The Kelvin probe according to claim 2, further comprising a holder integrally holding the first and second probe pins.

9. The Kelvin probe according to claim 3, further comprising a holder integrally holding the first and second probe pins.

10. The Kelvin probe according to claim 4, further comprising a holder integrally holding the first and second probe pins.

11. The Kelvin probe according to claim 5, further comprising a holder integrally holding the first and second probe pins.

12. A Kelvin inspection unit comprising the Kelvin probe according to claim 2 and a housing to house the Kelvin probe.

13. A Kelvin inspection unit comprising the Kelvin probe according to claim 3 and a housing to house the Kelvin probe.

14. A Kelvin inspection unit comprising the Kelvin probe according to claim 4 and a housing to house the Kelvin probe.

15. A Kelvin inspection unit comprising the Kelvin probe according to claim 5 and a housing to house the Kelvin probe.

16. A Kelvin inspection unit comprising the Kelvin probe according to claim 6 and a housing to house the Kelvin probe.
